(19) United States
(12) Patent Application Publication
(10) Pub. No.: US 2009/0321811 A1
(43) Pub. Date: Dec. 31, 2009

(54) MEMORY CELL TRANSISTORS HAVING BANDGAP-ENGINEERED TUNNELING INSULATOR LAYERS, NON-VOLATILE MEMORY DEVICES INCLUDING SUCH TRANSISTORS, AND METHODS OF FORMATION THEREOF

(75) Inventors: Chang Hyun Lee, Cambridge, MA (US); Jung Dal Choi, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd., Gyeonggi-do (KR)

(21) Appl. No.: 12/492,237

(22) Filed: Jun. 26, 2009

(30) Foreign Application Priority Data
Jun. 30, 2008 (KR) 10-2008-0062702

(51) Int. Cl. H01L 29/788; H01L 27/06

(52) U.S. Cl. 257/321; 257/E29.3; 257/E29.018; 257/E27.013

(57) ABSTRACT

A memory cell transistor comprises: an active region, the active region being elongated in a first direction of extension; a tunnel layer on the active region, the tunnel layer comprising a first tunnel insulating layer, a second tunnel insulating layer on the first tunnel insulating layer and a third tunnel insulating layer on the second tunnel insulating layer; a charge storage layer on the tunnel layer; a blocking insulating layer on the charge storage layer; and a control gate electrode on the blocking insulating layer, the control gate electrode being elongated in a second direction of extension that is transverse the first direction of extension, the active region having a first width in the second direction of extension, the second tunnel insulating layer having a second width in the second direction of extension, the second width being different than the first width.

### RELATED APPLICATIONS

This application claims priority under 35 U.S.C. 119 to Korean Patent Application No. 10-2008-0062702, filed on Jun. 30, 2008, the content of which is incorporated herein by reference in its entirety.

### BACKGROUND

With the continued emphasis on highly integrated electronic devices, there is an ongoing need for semiconductor memory devices that operate at higher speed and lower power and that have increased device density. To accomplish this, devices with aggressive scaling and multiple-layered devices with transistor cells arranged in horizontal and vertical arrays have been under development.

As devices continue to become increasingly scaled down in size, non-volatile memory cell transistors have been designed to include multiple-layered tunnel insulating layers. The tunnel insulating layers have become specifically designed to allow tunneling of holes into the charge storage layer during an erase or programming operation under high electric field conditions, while preventing charge migration during charge retention periods.

### SUMMARY

Embodiments of the present invention are directed to memory cell transistors and non-volatile memory devices including such transistors that address and overcome the limitations of the conventional approaches. Further, embodiments of the present invention are directed to methods of forming such transistors and memory devices that address and overcome such limitations.

In particular, embodiments of the present invention mitigate or eliminate leakage current in such devices, for example, by lengthening the leakage current pathway between the charge storage layer and the underlying active region. In one embodiment, the tunnel insulating layer includes lower, middle and upper layers, the active region is of a first width, and the middle layer of the tunnel insulating layer has a second width that is different than the first width of the active region. For example, in some embodiments, the second width of the middle tunnel insulating layer is greater than the first width of the active region, and in some embodiments, the second width of the middle tunnel insulating layer is less than the first width of the active region.

In one aspect, a memory cell transistor comprises: an active region, the active region being elongated in a first direction of extension; a tunnel layer on the active region, the tunnel layer comprising a first tunnel insulating layer, a second tunnel insulating layer on the first tunnel insulating layer and a third tunnel insulating layer on the second tunnel insulating layer; a charge storage layer on the tunnel layer; a blocking insulating layer on the charge storage layer; and a control gate electrode on the blocking insulating layer, the control gate electrode being elongated in a second direction of extension that is transverse the first direction of extension, the active region having a first width in the second direction of extension, the second tunnel insulating layer having a second width in the second direction of extension, the second width being different than the first width.

In one embodiment, the second tunnel insulating layer comprises a material that has a bandgap value that is lower than a bandgap value of a material of the first tunnel insulating layer and a material of the third tunnel insulating layer.

In another embodiment, the second tunnel insulating layer comprises a material that has a dielectric constant value that is higher than a dielectric constant value of a material of the first tunnel insulating layer and a material of the third tunnel insulating layer.

In another embodiment, the second width of the second tunnel insulating layer is greater than the first width of the active region so as to sufficiently increase a length of an edge leakage pathway between the charge storage layer and the active layer along side boundaries of the tunnel layer to thereby minimize electron or hole tunneling at edge regions of the tunnel layer, during programming and erase operations of the memory cell transistor.

In another embodiment, the second width of the second tunnel insulating layer is sufficiently less than the first width of the active region, to thereby minimize electron or hole tunneling at edge regions on the active region, during programming and erase operations of the memory cell transistor.

In another embodiment, the first width of the active region is greater than the second width of the second tunnel insulating layer of the tunnel layer.

In another embodiment, the first width of the active region is less than the second width of the second tunnel insulating layer of the tunnel layer.

In another embodiment, the charge storage layer is of a third width in the second direction of extension and wherein the third width of the charge storage layer is equal to the first width of the active region.

In another embodiment, the charge storage layer is of a third width in the second direction of extension and wherein the third width of the charge storage layer is greater than the first width of the active region.

In another embodiment, the charge storage layer is of a third width in the second direction of extension and wherein the third width of the charge storage layer is less than the first width of the active region.

In another embodiment, the charge storage layer is of a third width in the second direction of extension and wherein the third width of the charge storage layer is equal to the second width of the second tunnel insulating layer of the tunnel layer.

In another embodiment, the charge storage layer is of a third width in the second direction of extension and wherein the third width of the charge storage layer is greater than the second width of the second tunnel insulating layer of the tunnel layer.

In another embodiment, the charge storage layer is of a third width in the second direction of extension and wherein the third width of the charge storage layer is less than the second width of the second tunnel insulating layer of the tunnel layer.

In another embodiment, the active region is elongated in the first direction of extension and wherein the first direction of extension and the second direction of extension are perpendicular to each other.

In another embodiment, the second tunnel insulating layer and the charge storage layer are the same material.

In another embodiment, the first tunnel insulating layer comprises silicon oxide, wherein the second tunnel insulating layer comprises silicon nitride and wherein the third tunnel insulating layer comprises silicon oxide.

In another embodiment, the blocking insulating layer includes an opening and wherein the control gate electrode contacts the charge storage layer through the opening in the blocking insulating layer.

In another aspect a semiconductor memory device comprises: a plurality of active regions defined in a substrate, the active regions each being elongated in a first direction of extension; a plurality of isolating regions between the active regions, the isolating regions extending in the first direction; the isolating regions insulating the active regions from each other in a second direction of extension that is transverse the first direction; a tunnel layer on each of the plurality of active regions, the tunnel layer comprising a first tunnel insulating layer, a second tunnel insulating layer on the first tunnel insulating layer and a third tunnel insulating layer on the second tunnel insulating layer; a charge storage layer on the tunnel layer; a blocking insulating layer on the charge storage layer; and a control gate electrode on the blocking insulating layer, the control gate electrode being elongated in the second direction of extension, the active region having a first width in the second direction of extension, the second tunnel insulating layer having a second width in the second direction of extension, the second width being different than the first width; wherein each of the plurality of active regions extending in the first direction define a transistor string that includes a plurality of memory cell transistors arranged in series between a string select transistor and a ground select transistor, and wherein the semiconductor memory device further comprises: word lines extending in the second direction and connected to the control gate electrodes of corresponding memory cell transistors of different transistor strings; and bit lines extending in the first direction and connected to the string select transistors of different transistor strings.

In one embodiment, each second tunnel insulating layer comprises a material that has a bandgap value that is lower than a bandgap value of a material of the first tunnel insulating layer and a material of the third tunnel insulating layer.

In another embodiment, each second tunnel insulating layer comprises a material that has a dielectric constant value that is higher than a dielectric constant value of a material of the first tunnel insulating layer and a material of the third tunnel insulating layer.

In another embodiment, the second width of each second tunnel insulating layer is greater than the first width of the active region.

In another embodiment, the second width of the second tunnel insulating layer is sufficiently less than the first width of the active region.

In another embodiment, the first width of the active region is greater than the second width of the second tunnel insulating layer of the tunnel layer.

In another embodiment, the first width of each active region is less than the second width of the second tunnel insulating layer of the tunnel layer.

In another embodiment, each charge storage layer is of a third width in the second direction of extension and wherein the third width of the charge storage layer is equal to the first width of the active region.

In another embodiment, each charge storage layer is of a third width in the second direction of extension and wherein the third width of the charge storage layer is greater than the first width of the active region.

In another embodiment, each charge storage layer is of a third width in the second direction of extension and wherein the third width of the charge storage layer is less than the first width of the active region.

In another embodiment, the charge storage layer is of a third width in the second direction of extension and wherein the third width of the charge storage layer is equal to the second width of the second tunnel insulating layer of the tunnel layer.

In another embodiment, each charge storage layer is of a third width in the second direction of extension and wherein the third width of the charge storage layer is greater than the second width of the second tunnel insulating layer of the tunnel layer.

In another embodiment, each charge storage layer is of a third width in the second direction of extension and wherein the third width of the charge storage layer is less than the second width of the second tunnel insulating layer of the tunnel layer.

In another embodiment, each corresponding second tunnel insulating layer and charge storage layer are the same material

In another embodiment, the first tunnel insulating layer comprises silicon oxide, wherein the second tunnel insulating layer comprises silicon nitride and wherein the third tunnel insulating layer comprises silicon oxide.

In another embodiment, the blocking insulating layer includes an opening and wherein the control gate electrode contacts the charge storage layer through the opening in the blocking insulating layer.

In another aspect, a memory system comprises: a memory controller that generates command and address signals; and a memory module comprising a plurality of memory devices, the memory module receiving the command and address signals and in response storing and retrieving data to and from at least one of the memory devices, wherein each memory device comprises: a plurality of active regions defined in a substrate, the active regions each being elongated in a first direction of extension; a plurality of isolating regions between the active regions, the isolating regions extending in the first direction; the isolating regions insulating the active regions from each other in a second direction of extension that is transverse the first direction; a tunnel layer on each of the plurality of active regions, the tunnel layer comprising a first tunnel insulating layer, a second tunnel insulating layer on the first tunnel insulating layer and a third tunnel insulating layer on the second tunnel insulating layer; a charge storage layer on the tunnel layer; a blocking insulating layer on the charge storage layer; and a control gate electrode on the blocking insulating layer, the control gate electrode being elongated in the second direction of extension, the active region having a first width in the second direction of extension, the second tunnel insulating layer having a second width in the second direction of extension, the second width being different than the first width; wherein each of the plurality of active regions extending in the first direction define a transistor string that includes a plurality of memory cell transistors arranged in series between a string select transistor and a ground select transistor, and wherein the semiconductor memory device further comprises: word lines extending in the second direction and connected to the control gate electrodes of corresponding memory cell transistors of different transistor strings; and bit lines extending in the first direction and connected to the string select transistors of different transistor strings.

### BRIEF DESCRIPTION OF THE DRAWINGS

The foregoing and other objects, features and advantages of the embodiments of the invention will be apparent from the more particular description of preferred embodiments of the invention, as illustrated in the accompanying drawings in which like reference characters refer to the same parts throughout the different views. The drawings are not necessarily to scale, emphasis instead being placed upon illustrating the principles of the invention. In the drawings:

FIG. 1 is a circuit diagram of a non-volatile memory device including a memory cell array.

FIG. 2 is a top plan view of a memory cell array, in accordance with embodiments of the present invention.

FIG. 3 is a cross-sectional diagram of the memory cell array of FIG. 2, taken along section line I-I′ in accordance with an embodiment of the present invention.

FIG. 4 is a close-up cross-sectional view of one of the memory cells of FIGS. 2 and 3 in accordance with an embodiment of the present invention.

FIG. 5 is a close-up cross-sectional view of one of the memory cells of FIG. 3 in accordance with an another embodiment of the present invention.

FIG. 6 is a close-up cross-sectional view of one of the memory cells of FIG. 3 in accordance with an another embodiment of the present invention.

FIG. 7 is a close-up cross-sectional view of one of the memory cells of FIG. 3 in accordance with an another embodiment of the present invention.

FIG. 8 is a close-up cross-sectional view of a transistor device in accordance with an another embodiment of the present invention.

FIG. 9 is a close-up cross-sectional view of one of the memory cells of FIG. 3 in accordance with an another embodiment of the present invention.

FIGS. 10A-10F are cross-sectional diagrams of a method of forming the memory cell of a configuration of the type illustrated in FIG. 4 in accordance with an embodiment of the present invention.

FIGS. 11A-11C are cross-sectional diagrams of a method of forming the memory cell of a configuration of the type illustrated in FIG. 5 in accordance with an embodiment of the present invention.

FIGS. 12A-12D are cross-sectional diagrams of a method of forming the memory cell of a configuration of the type illustrated in FIG. 6 in accordance with an embodiment of the present invention.

FIGS. 13A-13B are cross-sectional diagrams of a method of forming a butting contact of a configuration of the type illustrated in the embodiment of FIG. 8, in accordance with an embodiment of the present invention.

FIGS. 14A-14B are cross-sectional diagrams of a method of forming the memory cell of a configuration of the type illustrated in FIG. 9 in accordance with an embodiment of the present invention.

FIG. 15A is a close-up cross-sectional view of a tunnel insulating layer of a previously researched bandgap-engineered (BE) SONOS device having a multiple-layered tunnel insulating layer. FIGS. 15B and 15C are close-up cross-sectional illustrations of a tunnel insulating layer of a memory device having a multiple-layered tunnel insulating layer in accordance with embodiments of the present invention.

FIG. 16A is a block diagram of a memory device in accordance with embodiments of the present invention. FIG. 16B is a block diagram of the memory cell array of the memory device of FIG. 16A, in accordance with embodiments of the present invention.

FIG. 17 is a block diagram of a memory card that includes a semiconductor device in accordance with the embodiments of the present invention.

FIG. 18 is a block diagram of a memory system that employs a memory module, for example, of the type described herein, in accordance with embodiments of the present invention.

### DETAILED DESCRIPTION OF EMBODIMENTS

Recently, devices have been configured to have bandgap-engineered (BE) tunnel insulating layers, and, in particular, BE-SONOS devices have been studied.

In some of BE-SONOS or MANOS type devices, the oxide-nitride-oxide (ONO) tunnel insulating layer barrier stack between the silicon-based (S) channel region and the silicon-based (S) charge storage region acquire bandgap properties that are specifically designed to provide improved low-field retention characteristics, while offering lowered programming and erase voltage properties. With further device integration, however, leakage current through the tunnel insulating layer is a limitation that designers must address.

Embodiments of the present invention will now be described more fully hereinafter with reference to the accompanying drawings, in which preferred embodiments of the invention are shown. This invention may, however, be embodied in different forms and should not be construed as limited to the embodiments set forth herein. Like numbers refer to like elements throughout the specification.

It will be understood that, although the terms first, second, etc. are used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.). When an element is referred to herein as being “over” another element, it can be over or under the other element, and either directly coupled to the other element, or intervening elements may be present, or the elements may be spaced apart by a void or gap. As mentioned above, the drawings are not necessarily to scale, and while certain features in the drawings appear to have rectangular edges that meet at right angles, those features in fact can be oval, contoured, or rounded in shape in the actual devices.

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

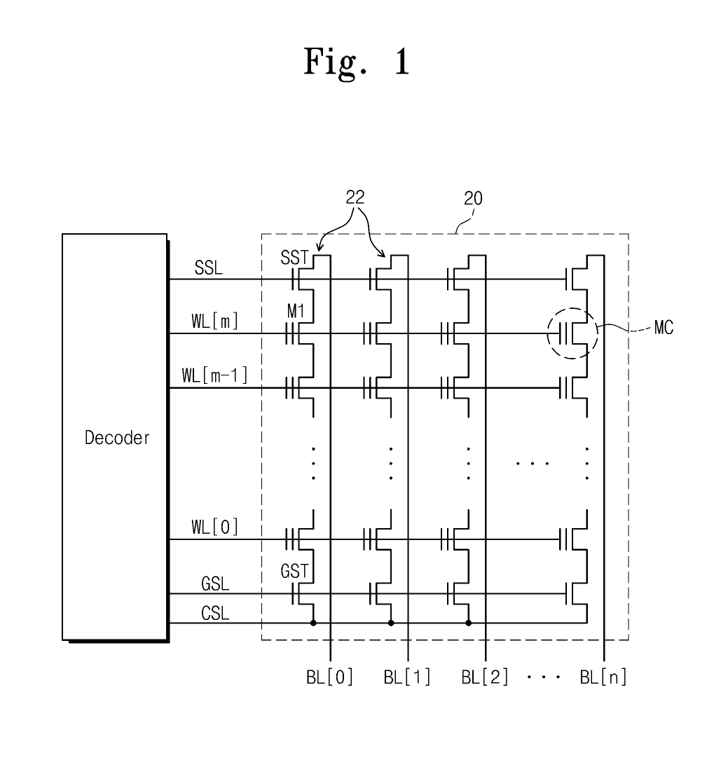

FIG. 1 is a circuit diagram of a non-volatile memory device including a memory cell array. Referring to FIG. 1, a memory cell array 20 includes a plurality of memory cells MC arranged in rows and columns. In each column, a plurality of memory cells MC are arranged in series between a string select transistor SST and a ground select transistor GST. Together, the plurality of memory cells MC, the string select transistor SST and the ground select transistor GST connected in series combine to form a cell string 22. A plurality of the cell strings 22 are similarly arranged between bit lines BL[0], BL[1], BL[2] . . . BL[n] and a common source line CSL. In this embodiment, the common source line CSL is connected to each of the ground select transistors GST of each string, as shown. Gates of corresponding ground select transistors GST are connected to a ground select line GSL of the device. Gates of corresponding string select transistors SST are connected to a string select line SSL of the device. Control gates of corresponding memory cell transistors MC of different cell strings 22 are connected to a word line WL[0] . . . WL[m] of the device. In this example, the reference letter “m” refers to the number of memory cell transistors MC[m] in each cell string 22, and the reference letter “n” refers to the number of cell strings 22 in the memory cell block 20. A decoder circuit 24 generates the signals for the string select line SSL, common source line CSL, ground select line GSL and word lines WL[m], to perform erase, program, read and write functions for the memory cell array 20.

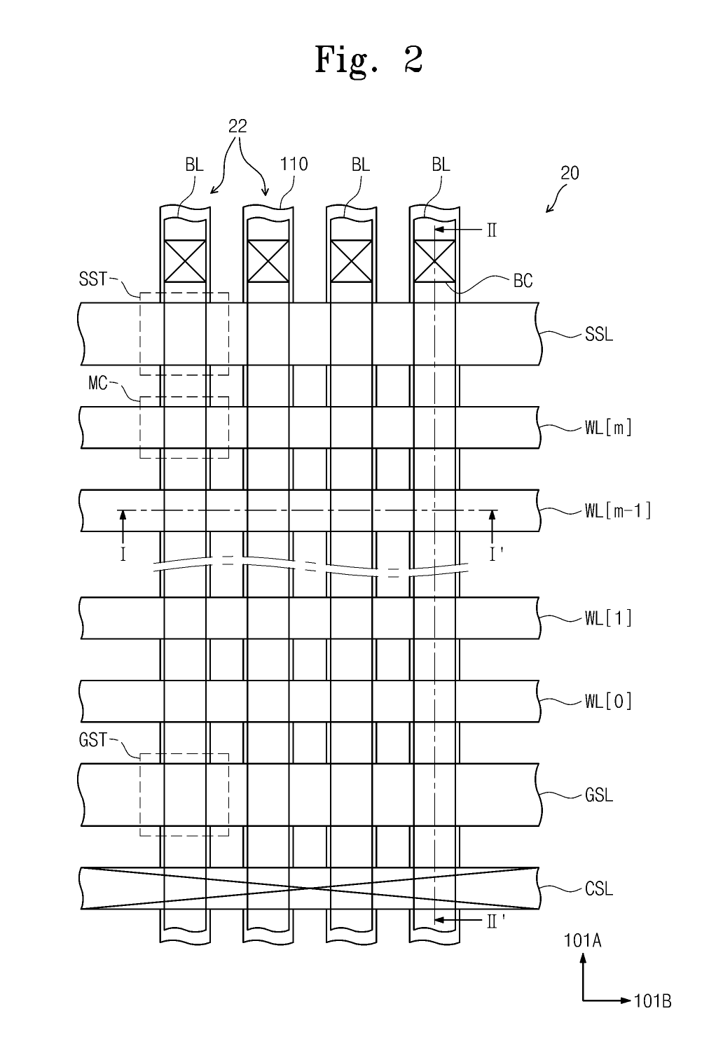

FIG. 2 is a top plan view of a memory cell array 20, in accordance with embodiments of the present invention. In this view, it can be seen that the string select line SSL, word lines WL[m], and ground select line GSL correspond to string select transistors SST, memory cell transistors MC and ground select transistors GST arranged in series between a bit line BL and a common source line CSL. An active region 110 of each cell string 22 extends in a first direction of extension 101A in a column direction of the device between the bit line contact BC and the common source line CSL. The string select line SSL, word lines WL[m], and ground select line GSL extend in a second direction of extension 101B, in a row direction of the device.

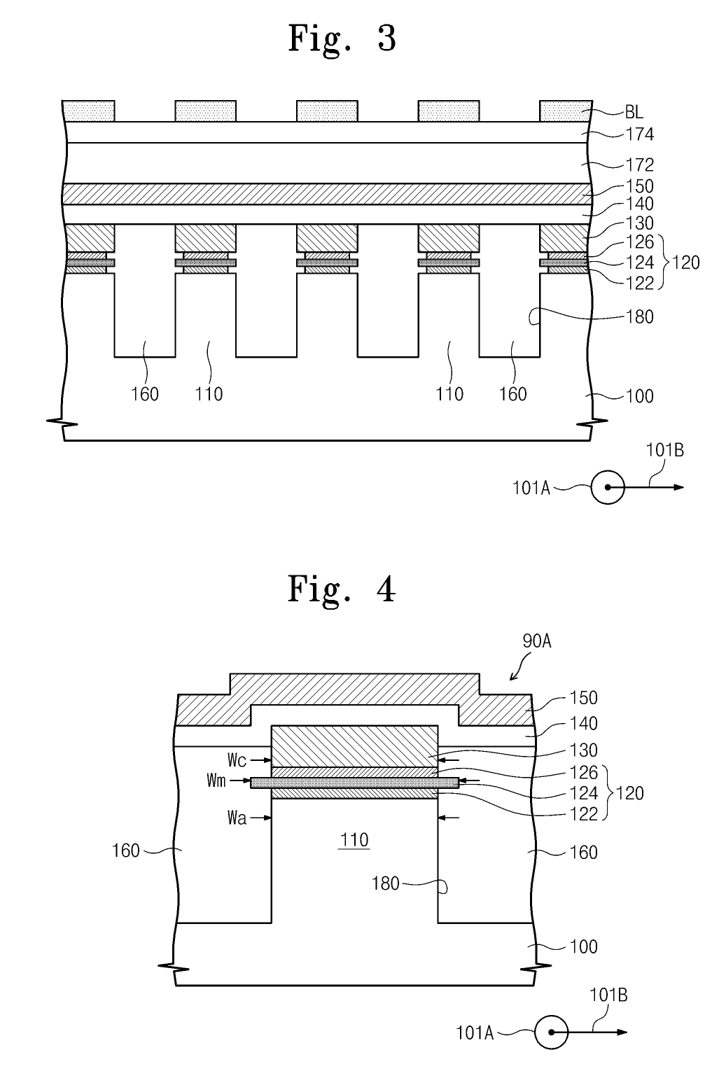

FIG. 3 is a cross-sectional diagram of the memory cell array of FIG. 2, taken along section line I-I′ in accordance with an embodiment of the present invention. In this view, it can be seen that a plurality of active regions 110 are on a substrate 100 and are separated from each other in the second direction of extension 101B by isolation structures 160 formed in trenches 180 between neighboring ones of the active regions 110. Referring to FIG. 2, the active regions 110 extend in a direction of the cell strings 22, referred to herein as a first direction of extension 101A that extends into and out of the page in this view. A tunnel insulation layer pattern 120 is positioned on the active regions 110 and, like the active regions 110, also extends in the first direction of extension 101A.

The tunnel insulation layer pattern 120 is comprised of multiple layers, for example, three layers, including a lower tunnel insulation layer pattern 122, a middle tunnel insulation layer pattern 124 and an upper tunnel insulation layer pattern 126. A charge storage layer pattern 130 is positioned on the tunnel insulation layer pattern 120 and, like the active regions 110 and the tunnel insulation layer pattern 120, extends in the first direction of extension 101A. In the embodiment shown, the isolation structures 160 further isolate elements of the tunnel insulation layer patterns 120 and elements of the charge storage layer pattern 130. A blocking layer 140 is positioned on the charge storage layer patterns 130.

A plurality of word lines 150 are positioned on the blocking layer 140. In one embodiment, the plurality of word lines run in parallel with each other and extend in a second direction of extension 101B, as shown in FIG. 2. A wordline 150 may be positioned on a planarized surface as seen in FIG. 3 or may vary in height due to difference in height between a gate structure and isolating layers as shown in the embodiment of FIG. 4. In one embodiment, the second direction of extension 101B can be transverse to the first direction of extension 101A, for example, perpendicular to the first direction of extension 101A, as shown in FIG. 2. Other angles between the first and second directions of extension 101A, 101B are also possible and equally applicable to the present embodiments. Lower and upper dielectric layers 172, 174 are provided on the plurality of word lines 150 and a plurality of bit lines BL are positioned on the dielectric layers 172, 174. In the embodiment shown, the bit lines BL, like the active regions 110, extend in the first direction of extension 101A, and correspond to the underlying active regions 110. In other embodiments, a single dielectric layer 172, or more than two dielectric layers 172, 174 may be provided.

FIG. 4 is a close-up cross-sectional view of one of the memory cells of FIGS. 2 and 3 in accordance with an embodiment of the present invention. In one example, memory cell 90A of FIG. 4 is representative of memory cell MC of FIG. 2. The memory cell 90A comprises an active region 110 provided on a substrate 100, a tunnel layer 120 on the active region 110, and a charge storage layer 130 on the tunnel layer 120. As described above, the active region 110 extends in the first direction of extension 101A, and, optionally, the tunnel layer 120 and the charge storage layer 130 can be patterned to likewise extend in the first direction of extension 101A. Alternatively, the tunnel layer 120 or the charge storage layer 130 can also be patterned in the first direction to comprise multiple, separate, elements in the first direction of extension 101A.

A blocking layer 140 is present on the charge storage layer 130 and a control gate electrode 150 is on the blocking layer 140. In another embodiment for memory devices, the control gate electrodes of neighboring memory cells may be connected to operate as a word line of the resulting device. In the present disclosure, the term “control gate electrode” can be used interchangeably with the term “word line”.

In the embodiment of FIG. 4, it can be seen that the middle tunnel layer 124 has a width Wm in the second direction 101B that is greater than a width Wa of the active region 110 in the second direction 101B. In addition, it can be seen that the width Wm of the middle tunnel layer 124 is greater that a width Wc of the charge storage layer 130 in the second direction 101B. In this manner, the middle tunnel layer 124 can be said to protrude relative to the active region 110 in the second direction 101B, and can be said to protrude relative to the charge storage layer 130 in the second direction 101B. In this regard, it should be noted that the drawings express some features in exaggerated format or structure to emphasize certain principles of the embodiments of the present specification. Given that, in some examples, the top surface of the active region may not be of a sharp edge and the edge of the surface may be rounded, which is also within the scope of the invention. For a rounded edge, the width of the active region is regarded as the width wherein the widths of rounded portions are also included.

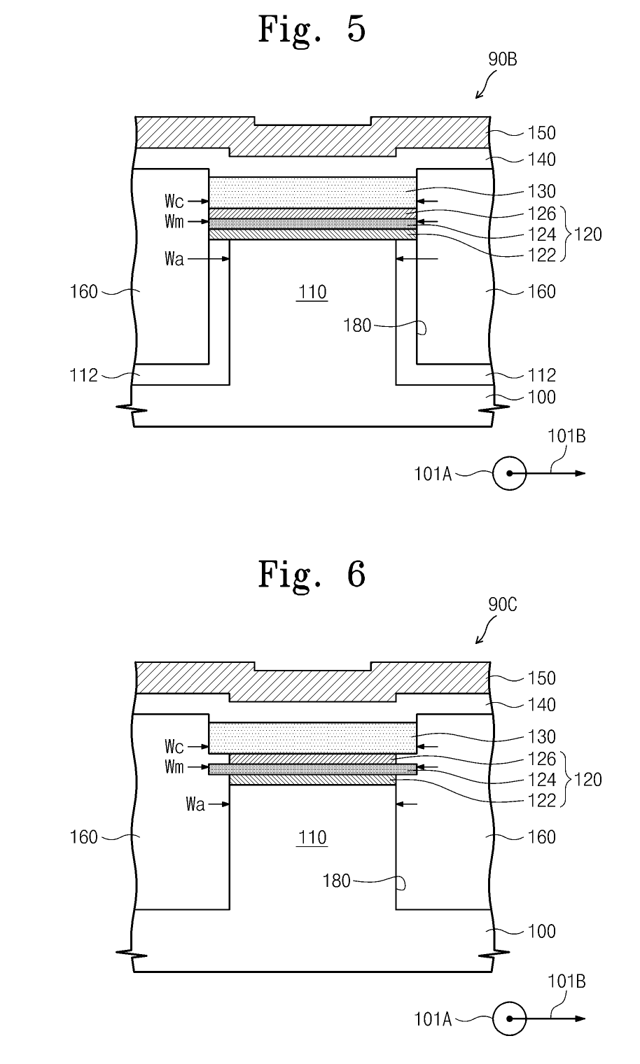

FIG. 5 is a close-up cross-sectional view of one of the memory cells of FIG. 3 in accordance with an another embodiment of the present invention. The memory cell 90B of FIG. 5 comprises an active region 110 provided on a substrate 100, a tunnel layer 120 on the active region 110, and a charge storage layer 130 on the tunnel layer 120. As described above, the active region 110 extends in the first direction of extension 101A, and, optionally, the tunnel layer 120 and the charge storage layer 130 can be patterned to likewise extend in the first direction of extension 101A. Alternatively, the tunnel layer 120 or the charge storage layer 130 can also be patterned in the first direction to comprise multiple, separate, elements in the first direction of extension 101A. A blocking layer 140 is present on the charge storage layer 130 and a control gate electrode 150 is on the blocking layer 140.

In the embodiment of FIG. 5, a selective oxidation layer 112 is formed on the sidewalls of the active region 110 and on an upper surface of the substrate 100 in the trenches 180. The tunnel layer 120 is provided on the upper surface of the active region 110. In this manner, the middle tunnel layer 124 has a width Wm in the second direction 101B that is greater than a width Wa of the active region 110 in the second direction 101B. In addition, in this embodiment, it can be seen that the width Wm of the middle tunnel layer 124 is the same as a width Wc of the charge storage layer 130 in the second direction 101B. In this manner, the middle tunnel layer 124 protrudes relative to the active region 110 in the second direction 101B.

FIG. 6 is a close-up cross-sectional view of one of the memory cells of FIG. 3 in accordance with an another embodiment of the present invention. The memory cell 90C of FIG. 6 comprises an active region 110 provided on a substrate 100, a tunnel layer 120 on the active region 110, and a charge storage layer 130 on the tunnel layer 120. As described above, the active region 110 extends in the first direction of extension 101A, and, optionally, the tunnel layer 120 and the charge storage layer 130 can be patterned to likewise extend in the first direction of extension 101A. Alternatively, the tunnel layer 120 or the charge storage layer 130 can also be patterned in the first direction to comprise multiple, separate, elements in the first direction of extension 101A. A blocking layer 140 is present on the charge storage layer 130 and a control gate electrode 150 is on the blocking layer 140.

The embodiment of FIG. 6 is substantially similar in configuration to that of the embodiment of FIG. 4, except that in the embodiment of FIG. 6, the charge storage layer 130 has a width Wc in the second direction 101B that is equal to, or greater than, a width Wm of the middle tunnel layer 124. As seen in FIG. 6, the upper surface of the charge storage layer may be lower than or higher than the top surface of the isolating layer. As in the embodiment of FIG. 4, the middle tunnel layer 124 of the embodiment of FIG. 6 has a width Wm in the second direction 101B that is greater than a width Wa of the active region 110 in the second direction 101B. In this manner, the middle tunnel layer 124 protrudes relative to the active region 110 in the second direction 101B.

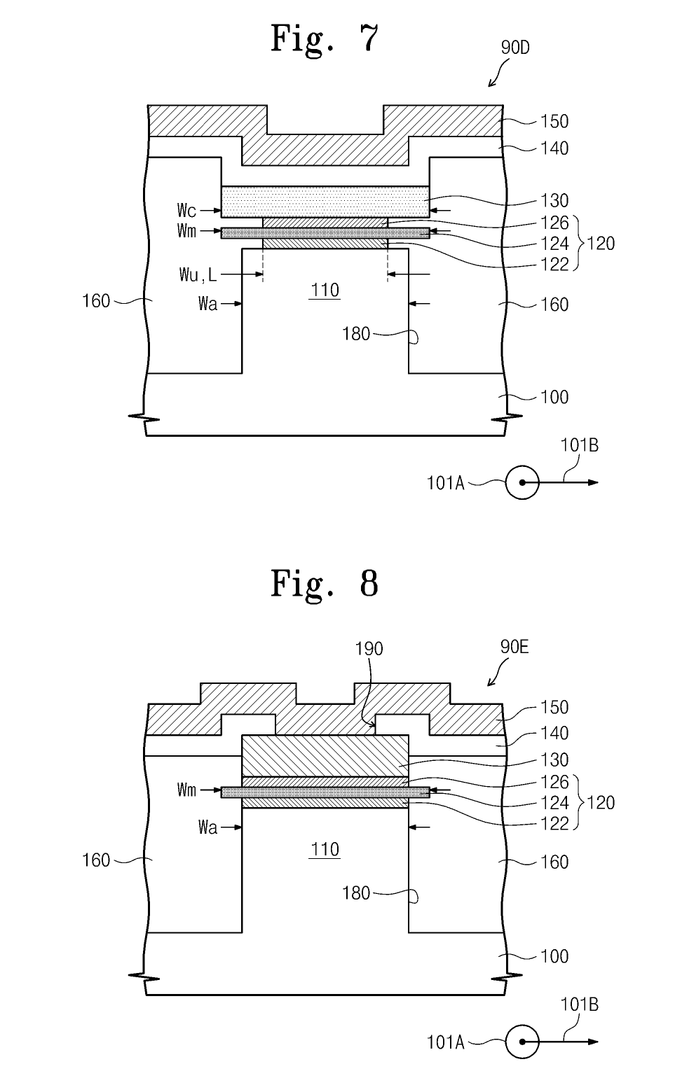

FIG. 7 is a close-up cross-sectional view of one of the memory cells of FIG. 3 in accordance with an another embodiment of the present invention. The memory cell 90D of FIG. 7 comprises an active region 110 provided on a substrate 100, a tunnel layer 120 on the active region 110, and a charge storage layer 130 on the tunnel layer 120. As described above, the active region 110 extends in the first direction of extension 101A, and, optionally, the tunnel layer 120 and the charge storage layer 130 can be patterned to likewise extend in the first direction of extension 101A. Alternatively, the tunnel layer 120 or the charge storage layer 130 can also be patterned in the first direction to comprise multiple, separate, elements in the first direction of extension 101A. A blocking layer 140 is present on the charge storage layer 130 and a control gate electrode 150 is on the blocking layer 140.

The embodiment of FIG. 7 is substantially similar in configuration to that of the embodiment of FIG. 6, except that in the embodiment of FIG. 7, the upper tunnel layer 126 and the lower tunnel layer 122 are recessed relative to the middle tunnel layer 124 of the tunnel layer 120 and relative to the active region 110 so that the widths of the upper tunnel layer and lower tunnel layer Wu,l are less than the width Wa of the active region 110 in the second direction 101B. As in the FIG. 6 embodiment, the charge storage layer 130 has a width Wc in the second direction 101B that is equal to or greater than a width Wm of the middle tunnel layer 124. Also, as in the FIG. 6 embodiment, the middle tunnel layer 124 has a width Wm in the second direction 101B that is greater than a width Wa of the active region 110 in the second direction 101B. In this manner, the middle tunnel layer 124 protrudes relative to the active region 110 in the second direction 101B.

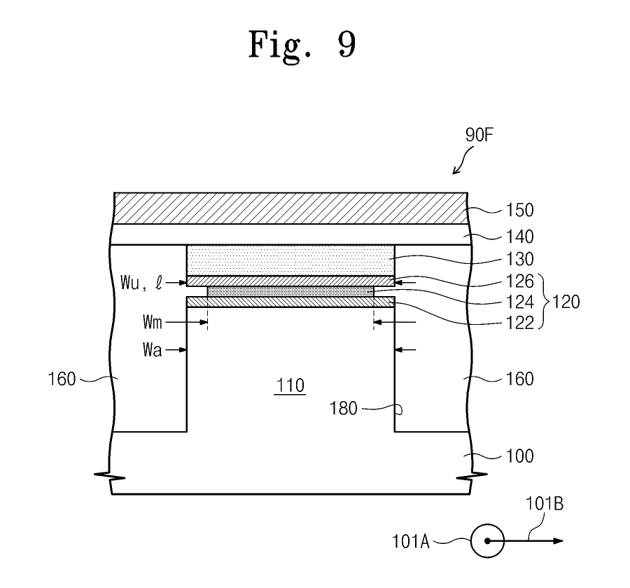

FIG. 8 is a close-up cross-sectional view of a transistor device in accordance with an another embodiment of the present invention. The transistor configuration 90E of FIG. 8 is similar in configuration to the memory cell 90A of FIG. 4, except that in the embodiment of FIG. 8, the device 90E is configured as a transistor, rather than as a non-volatile memory cell 90A. In particular, in the embodiment of FIG. 8, the control gate electrode 150, or word line, is a butting contact that makes direct contact with the underlying charge storage layer 130, in this example, a charge storage layer in the form of a floating gate electrode, through the blocking layer 140 at opening 190. Since direct contact with the charge storage layer 130 is made at the opening 190, the resulting device 90E operates as a conventional transistor in this embodiment, rather than as a memory cell. In one example, the transistor 90 of the present embodiment can be used as a string select transistor SST or ground select transistor GST of the cell strings 22 of the memory cell array 20 of FIGS. 1 and 2. As in the embodiments of FIGS. 4-7, the middle tunnel layer 124 has a width Wm in the second direction 101B that is greater than a width Wa of the active region 110 in the second direction 101B. In this manner, the middle tunnel layer 124 protrudes relative to the active region 110 in the second direction 101B.

FIG. 9 is a close-up cross-sectional view of one of the memory cells of FIG. 3 in accordance with an another embodiment of the present invention. The memory cell 90F of FIG. 9 comprises an active region 110 provided on a substrate 100, a tunnel layer 120 on the active region 110, and a charge storage layer 130 on the tunnel layer 120. As described above, the active region 110 extends in the first direction of extension 101A, and, optionally, the tunnel layer 120 and the charge storage layer 130 can be patterned to likewise extend in the first direction of extension 101A. Alternatively, the tunnel layer 120 or the charge storage layer 130 can also be patterned in the first direction to comprise multiple, separate, elements in the first direction of extension 101A. A blocking layer 140 is present on the charge storage layer 130 and a control gate electrode 150 is on the blocking layer 140.

The embodiment of FIG. 9 is substantially similar in configuration to that of the embodiment of FIG. 4, except that in the embodiment of FIG. 9, the middle tunnel layer 124 is recessed relative to the upper tunnel layer 126 and the lower tunnel layer 122. In this manner, the width of the middle tunnel layer Wm is less than the widths of the upper tunnel layer and lower tunnel layer Wu,l in the second direction 101B. Also, in the present embodiment, the width of the middle tunnel layer Wm is less than the width Wa of the active region 110 in the second direction 101B. In this manner, the middle tunnel layer 124 is recessed relative to the active region 110 in the second direction 101B.

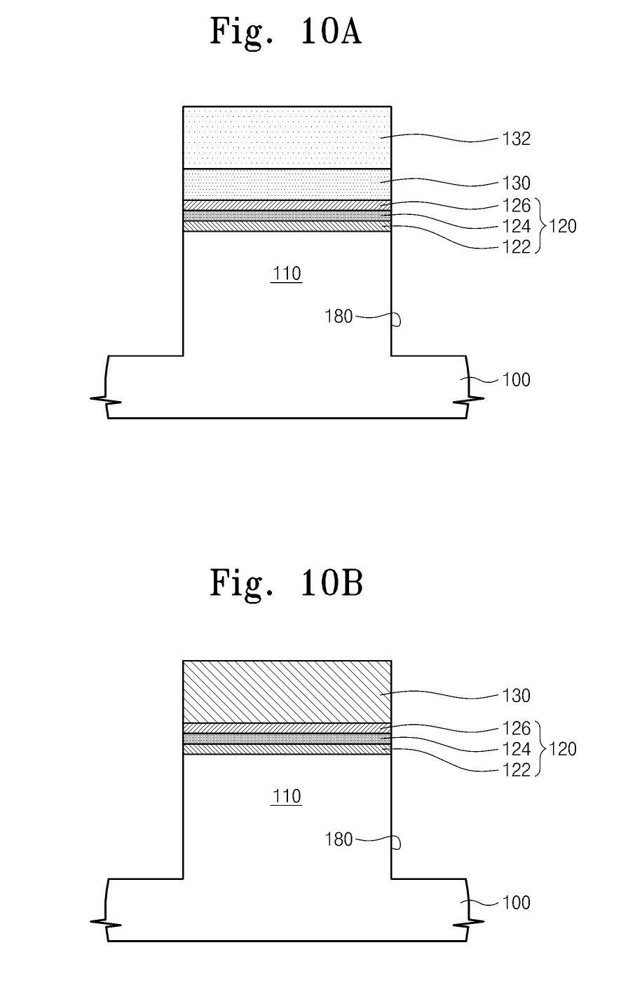

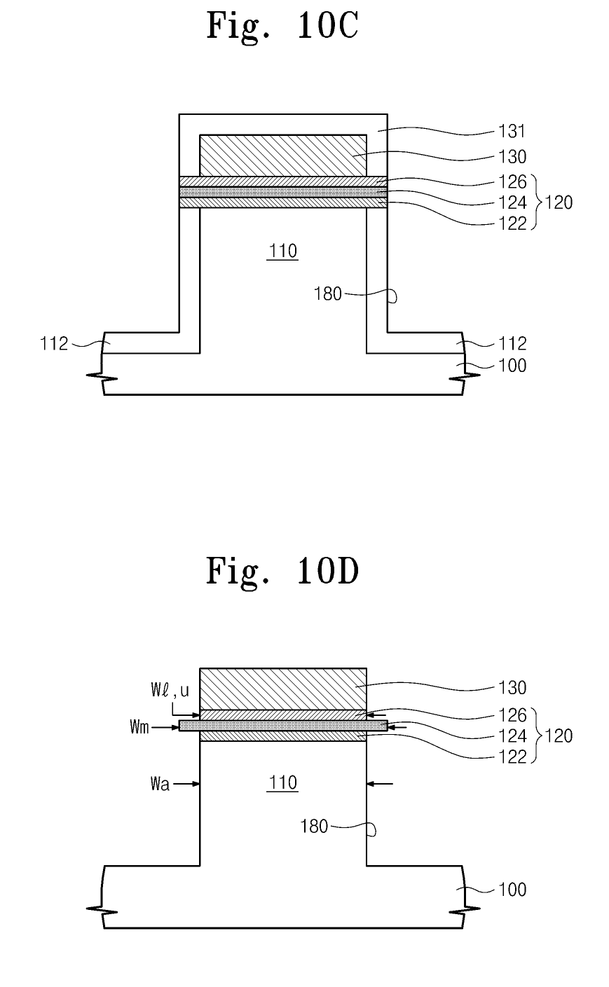

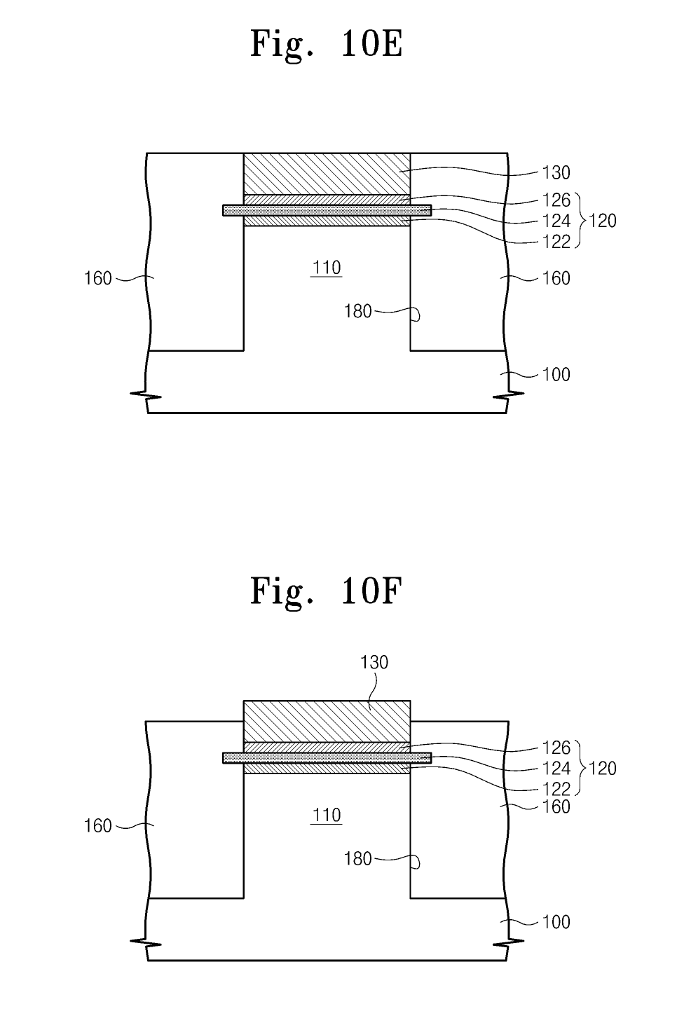

FIGS. 10A-10F are cross-sectional diagrams of a method of forming the memory cell of a configuration of the type illustrated in FIG. 4 in accordance with an embodiment of the present invention. Referring to FIG. 10A, a tunnel layer 120 and a charge storage layer 130 are stacked on a substrate 100. A hard mask layer is patterned to form a hard mask pattern 132. The hard mask pattern 132 is used as a mask for etching trenches 180 that define active regions 110 extending in the first direction 101A, as described above. Alternatively, the trenches and active regions 110 defined thereby can be formed by photolithographic patterning.

The substrate 100 comprises, for example, a silicon-based semiconductor substrate, including, but not limited to a bulk substrate or silicon-on-insulator SOI substrate. Other applicable substrate 100 materials and active region 110 materials are equally applicable to the present inventive concepts.

As described above, the tunnel layer 120 comprises multiple layers, for example, three layers, including a lower tunnel insulation layer pattern 122, a middle tunnel insulation layer pattern 124 and an upper tunnel insulation layer pattern 126. The lower tunnel layer 122 can be formed, for example, using a thermal oxidation process, for example, in-situ steam generation. Alternatively, the lower tunnel layer 122 can be formed using atomic layer deposition ALD of silicon oxide, metal oxide, or silicon nitride. The middle tunnel layer 124 can be formed, for example, using chemical vapor deposition CVD or ALD. The middle tunnel layer 124 can comprise, for example, silicon nitride, silicon oxynitride, and a high-k material such as Al₂O₃, HfO₂, HfAlO, HfSiO, ZrO₂, and Ta₂O₅. The upper tunnel layer 126 can be formed of a material similar to that of the lower tunnel layer 122, or, alternatively, can be formed of a material that is different from that of the lower tunnel layer 122.

The charge storage layer 130 can be formed of a suitable charge storage material, such as silicon nitride, metal quantum dot structures, silicon quantum dot structures, doped silicon, doped germanium, nano-crystalline silicon, nano-crystalline germanium, and nano-crystalline metal. Floating gate configurations can also be used for the charge storage layer 130.

The hard mask layer 132 can be formed of any suitable hard mask material, including, for example, SiON or SiN. The hard mask layer 132 can be formed of a material that has etch selectivity with respect to the material of the charge storage layer 130.

Referring to FIG. 10B, the trenches 180 are formed using the hard mask pattern 132 as an etch mask, and the hard mask pattern 132 is removed, thereby patterning the active regions 110, the tunnel layers 120 and the charge storage layer 130.

Referring to FIG. 10C, a selective oxidation of the resulting structure is performed, oxidizing exposed portions of the sidewalls of the active region 110 and the upper surface of the substrate 100 in the trenches 180 to form an oxidation region 131. In a case where the charge storage layer 130 is formed of a floating gate material, exposed portions of the charge storage layer 130 can also be oxidized by the selective oxidation process to form an oxidation region 131, as shown in FIG. 10C. In a case where the charge storage layer 130 is not formed of a material that can be oxidized, the charge storage layer 130 will remain essentially intact during this process step, thereby resulting in the memory cell configuration of FIG. 6, rather than the embodiment of FIG. 4.

Referring to FIG. 10D, a selective isotropic etching is performed on the resulting structure. As a result, the oxidation region 131 is removed. Also removed during the etching step are exposed side portions of the lower tunnel layer 122 and the upper tunnel layer 126. In this manner, the resulting widths Wl,u of the lower tunnel layer 122 and the upper tunnel layer 126 in the second direction 101B are less than the width Wm of the middle tunnel layer 124, as the middle tunnel layer 124, is essentially left intact as a result of the selective isotropic etching process. In addition the resulting width Wa of the active region 110 in the second direction 101B is less than the width Wm of the middle tunnel layer 124.

Referring to FIG. 10E, a trench fill process is performed on the resulting structure, for example, using silicon oxide SiO₂, thereby filling the trenches 180 to provide isolation structures 160 between neighboring ones of the active regions 110. The resulting structure is then planarized using chemical-mechanical polishing CMP, or processed in a wet etch process, to expose an upper portion of the charge storage layer 130.

Referring to FIG. 10F, through further etching, or by extending the CMP process, upper portions of sidewalls of the charge storage layer 130 are exposed. Following this, a blocking insulating layer 140 is formed on the resulting structure, and word lines are formed and patterned on the blocking insulating layer 140 to extend in the second direction 101B. As a result, the memory cell configuration 90A of FIG. 4 is thereby formed.

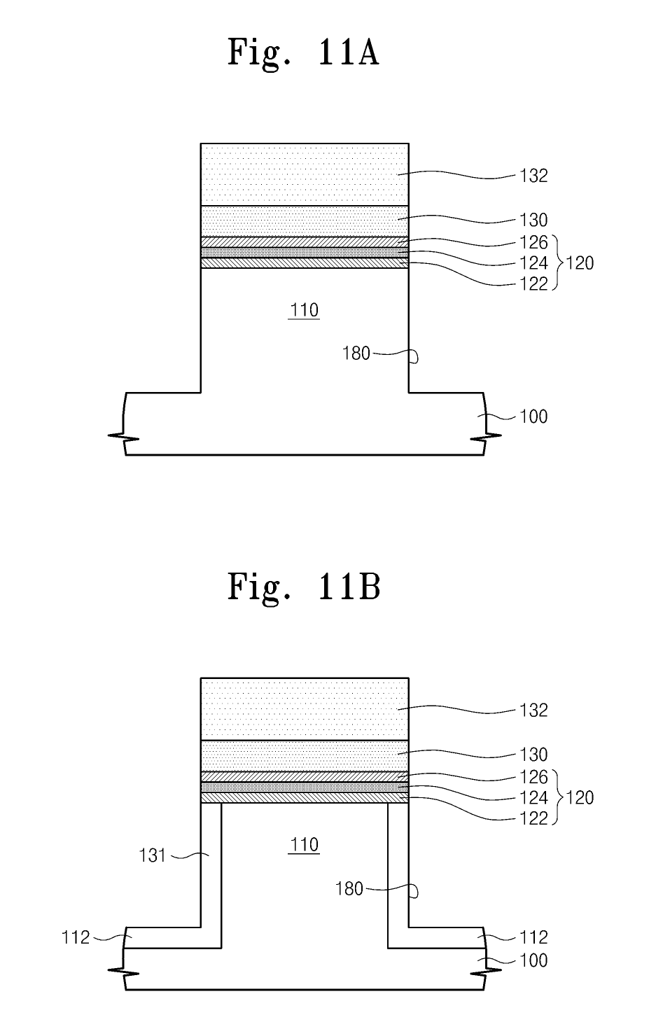

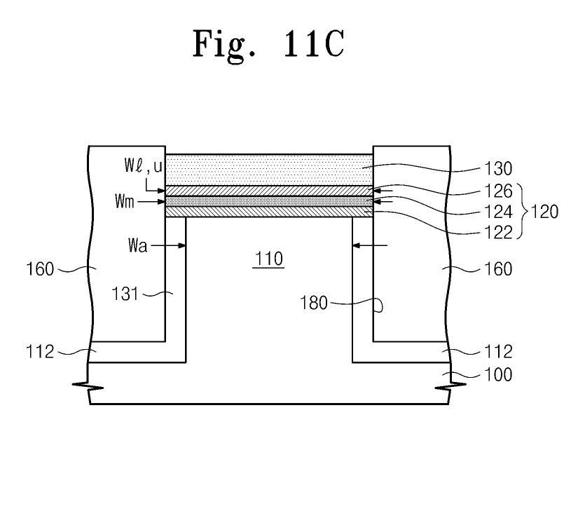

FIGS. 11A-11C are cross-sectional diagrams of a method of forming the memory cell of a configuration of the type illustrated in FIG. 5 in accordance with an embodiment of the present invention. In this embodiment, it is assumed that the charge storage layer 130 is formed of a material that either will not oxidize, or will be minimally oxidized, when subject to an selective oxidation processing step.

Referring to FIG. 11A, a substrate is prepared according to the steps discussed above in connection with FIG. 10A.

Referring to FIG. 11B, the trenches 180 are formed using the hard mask pattern 132 as an etch mask, thereby patterning the active regions 110, the tunnel layers 120 and the charge storage layer 130. A selective oxidation of the resulting structure is performed with the hard mask pattern 132 intact, oxidizing exposed portions of the sidewalls of the active region 110 and the upper surface of the substrate 100 in the trenches 180 to form an oxidation region 131. In this case, since the charge storage layer 130 is not formed of a material that can be oxidized or can only be minimally oxidized, the charge storage layer 130 will remain essentially intact during this process step, thereby resulting in the memory cell configuration of FIG. 5, rather than the embodiment of FIG. 4. The charge storage layer may be a charge trap layer, for example comprised of SiN or nanoparticle, etc.

Referring to FIG. 11C, a trench fill process is performed on the resulting structure, for example, using silicon oxide SiO₂, thereby filling the trenches 180 to provide isolation structures 160 between neighboring ones of the active regions 110. The oxidation regions 131 remain in this example embodiment. The resulting structure is then planarized using chemical-mechanical polishing CMP, or processed in a wet etch process, to expose an upper portion of the charge storage layer 130.

In this manner, the resulting widths Wl,u of the lower tunnel layer 122 and the upper tunnel layer 126 in the second direction 101B are the same as the width Wm of the middle tunnel layer 124. In addition the resulting width Wa of the active region 110 in the second direction 101B is less than the width Wm of the middle tunnel layer 124.

Following this, a blocking insulating layer 140 is formed on the resulting structure, and word lines are formed and patterned on the blocking insulating layer 140 to extend in the second direction 101B. As a result, the memory cell configuration 90B of FIG. 5 is thereby formed.

In an alternative embodiment of the process of FIGS. 11A-11C, the width Wa of the active region 110 can be further selectively reduced. Following the selective oxidation during the step described above in connection with FIG. 11B, the resulting oxidation regions 131 can be selectively removed and then the resulting exposed sidewalls of the active region 110 can be subjected to a second selective oxidation step. In this manner, the resulting width Wa of the active region 110 can be further reduced.

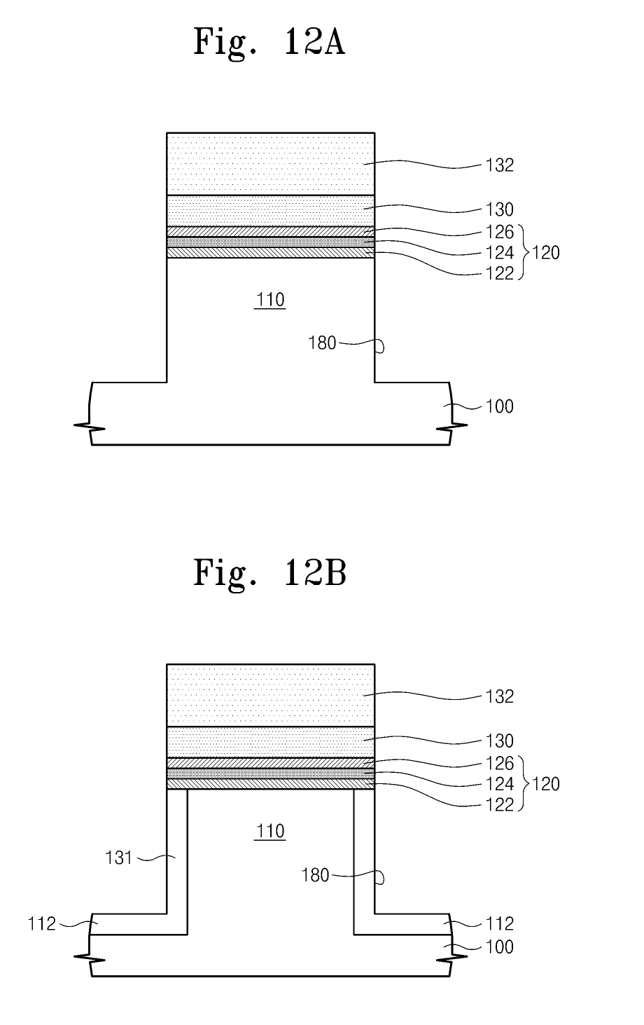

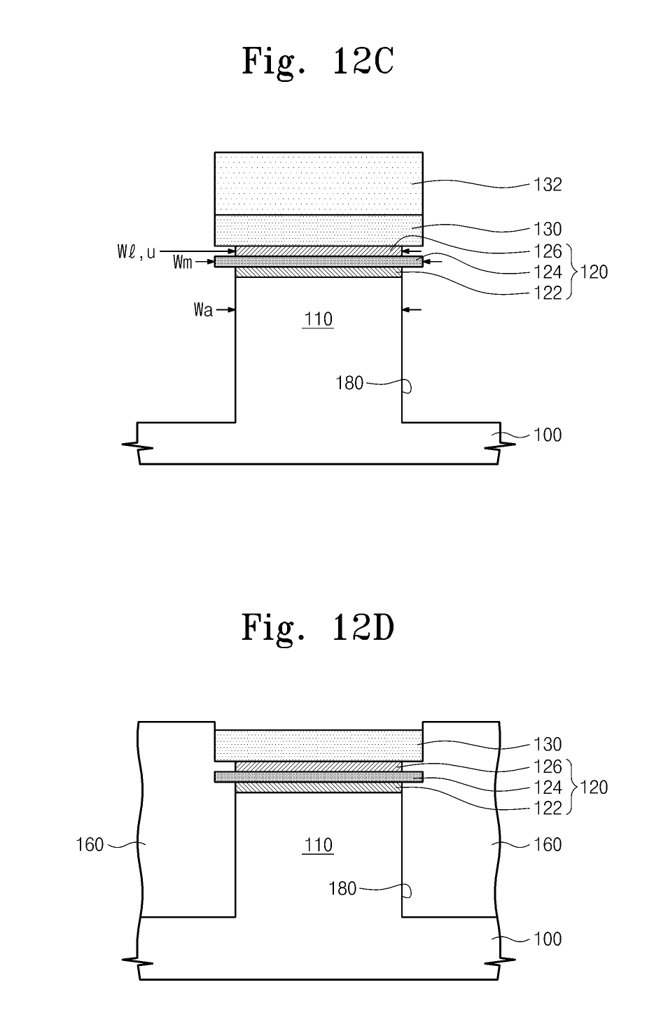

FIGS. 12A-12D are cross-sectional diagrams of a method of forming the memory cell of a configuration of the type illustrated in FIG. 6 in accordance with an embodiment of the present invention.

Referring to FIG. 12A, a substrate is prepared according to the steps discussed above in connection with FIG. 10A.

Referring to FIG. 12B, the trenches 180 are formed using the hard mask pattern 132 as an etch mask, thereby patterning the active regions 110, the tunnel layers 120 and the charge storage layer 130. A selective oxidation of the resulting structure is performed with the hard mask pattern 132 intact, oxidizing exposed portions of the sidewalls of the active region 110 and the upper surface of the substrate 100 in the trenches 180 to form an oxidation region 131. In this case, since the charge storage layer 130 is not formed of a material that can be oxidized or can only be minimally oxidized, the charge storage layer 130 will remain essentially intact during this process step, thereby resulting in the memory cell configuration of FIG. 6, rather than the embodiment of FIG. 4.

Referring to FIG. 12C, a selective isotropic etching is performed on the resulting structure. As a result, the oxidation region 131 is removed. Also removed are exposed side portions of the lower tunnel layer 122 and the upper tunnel layer 126. In this manner, the resulting widths Wl,u of the lower tunnel layer 122 and the upper tunnel layer 126 in the second direction 101B are less than the width Wm of the middle tunnel layer 124, as the middle tunnel layer 124, is essentially left intact as a result of the selective isotropic etching process. In addition the resulting width Wa of the active region 110 in the second direction 101B is less than the width Wm of the middle tunnel layer 124. The removal of the upper tunnel layer and lower tunnel layer may be performed at the same or different speeds. Thus, the level of recess may be same or different.

Referring to FIG. 12D, a trench fill process is performed on the resulting structure, for example, using silicon oxide SiO₂, thereby filling the trenches 180 to provide isolation structures 160 between neighboring ones of the active regions 110. The resulting structure is then planarized using chemical-mechanical polishing CMP, or processed in a wet etch process, to expose an upper portion of the charge storage layer 130. Following this, a blocking insulating layer 140 is formed on the resulting structure, and word lines are formed and patterned on the blocking insulating layer 140 to extend in the second direction 101B. As a result, the memory cell configuration 90C of FIG. 6 is thereby formed.

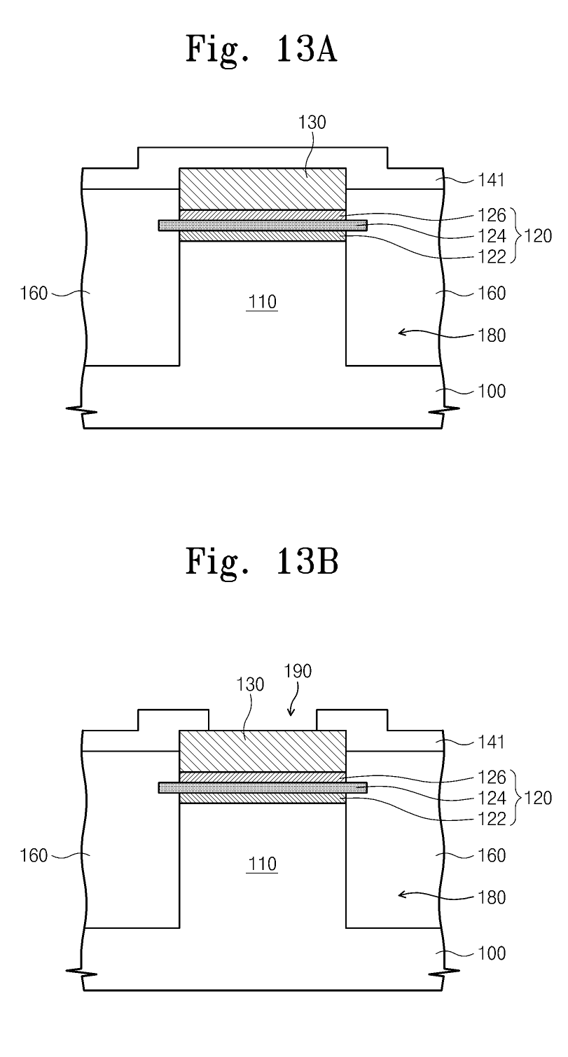

FIGS. 13A-13B are cross-sectional diagrams of a method of forming a butting contact of a configuration of the type illustrated in the embodiment of FIG. 8, in accordance with an embodiment of the present invention.

Referring to FIG. 13A, a transistor is prepared according to the steps discussed above in connection with FIGS. 10A-10F. After forming a gate structure, trenches are filled with isolating material to form an isolating layer. Following this, through further etching such as wet etching, or by extending the CMP process, upper portions of sidewalls of the charge storage layer 130 are exposed. Then, a blocking insulating layer 141 is conformally formed on the resulting structure.

Referring to FIG. 13B, the blocking insulating layer 140 or 141 is patterned to form an opening 190. Word lines 150 (see FIG. 8) are formed and patterned on the blocking insulating layer 141 to extend in the second direction 101B. The word lines 150 make direct contact with the underlying charge storage layer 130, through the blocking layer 141 at opening 190. As result, the resulting device 90E as shown in FIG. 8 operates as a conventional transistor, as described above.

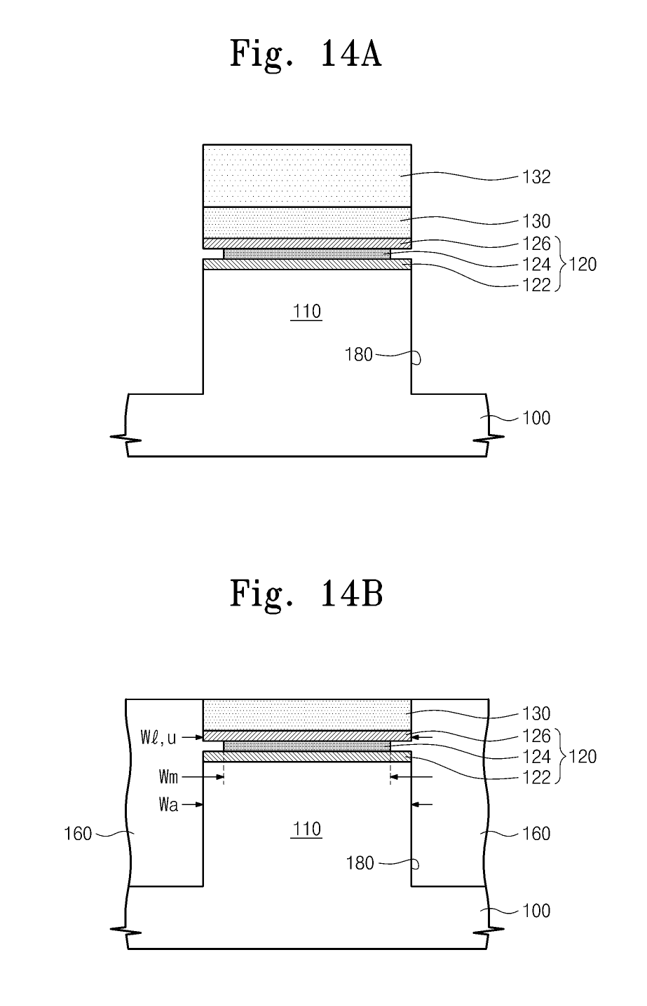

FIGS. 14A-14B are cross-sectional diagrams of a method of forming the memory cell of a configuration of the type illustrated in FIG. 9 in accordance with an embodiment of the present invention.

Referring to FIG. 14A, a substrate is prepared according to the steps discussed above in connection with FIG. 10A. The trenches 180 are formed using the hard mask pattern 132 as an etch mask, thereby patterning the active regions 110, the tunnel layers 120 and the charge storage layer 130. After forming a trench, the trench can be filled with isolating materials to form a shallow trench isolation (STI) structure. This is followed by the forming of a tunneling layer and stacking charge storage layer, a blocking layer and a conductive layer for a control gate, and then the layers are patterned. Next, after the gate structure is formed, with the sides of the gate structure exposed, selective etching, using the difference of etch rate, is performed to form a recess of the middle tunnel layer in the direction of extension of the wordlines, for example in the 101B direction.

Referring to FIG. 14B, a trench fill process is performed on the resulting structure, for example, using silicon oxide SiO₂, thereby filling the trenches 180 to provide isolation structures 160 between neighboring ones of the active regions 110. The resulting structure is then planarized using chemical-mechanical polishing CMP, or processed in a wet etch process, to expose an upper portion of the charge storage layer 130.

In this manner, the resulting widths Wl,u of the lower tunnel layer 122 and the upper tunnel layer 126 in the second direction 101B are greater than the width Wm of the middle tunnel layer 124 in the second direction 101B. In addition the resulting width Wa of the active region 110 in the second direction 101B is greater than the width Wm of the middle tunnel layer 124 in the second direction 101B.

Following this, a blocking insulating layer 140 (see FIG. 9) is formed on the resulting structure, and word lines 150 are formed and patterned on the blocking insulating layer 140 to extend in the second direction 101B. As a result, the memory cell configuration 90F of FIG. 9 is thereby formed.

In the above embodiments of FIGS. 4-8, in contrast, it can be seen that the middle tunnel layer 124 protrudes in the second direction of extension 101B relative to the active region 110. The middle tunnel layer 124 thus has a width Wm in the second direction of extension 101B that is greater than a width Wa of the active region 110 in the second direction 101B.

In the above embodiment of FIG. 9, it can be seen that the middle tunnel layer 124 is recessed in the second direction of extension 101B relative to the active region 110. The middle tunnel layer 124 thus has a width Wm in the second direction of extension 101B that is less than a width Wa of the active region 110 in the second direction 101B.

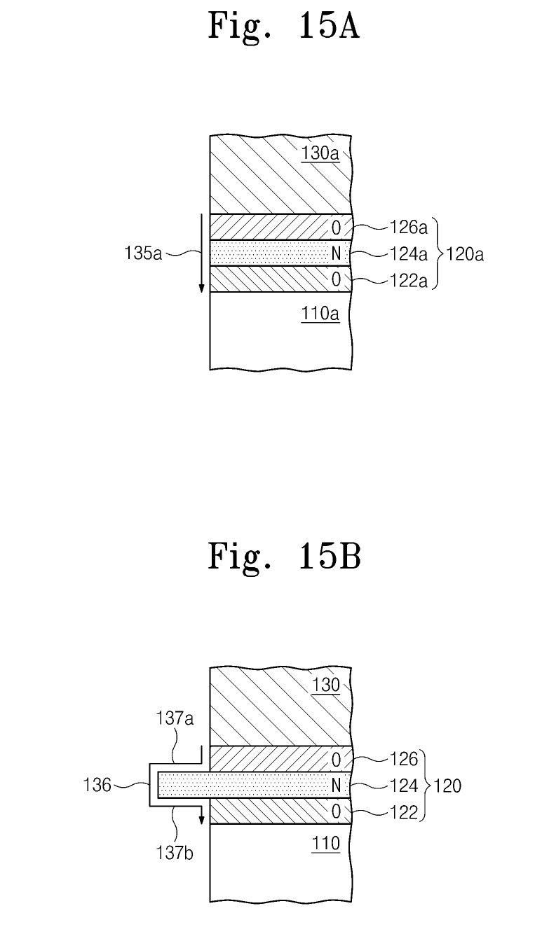

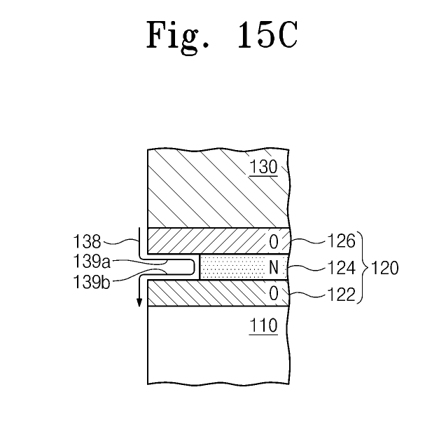

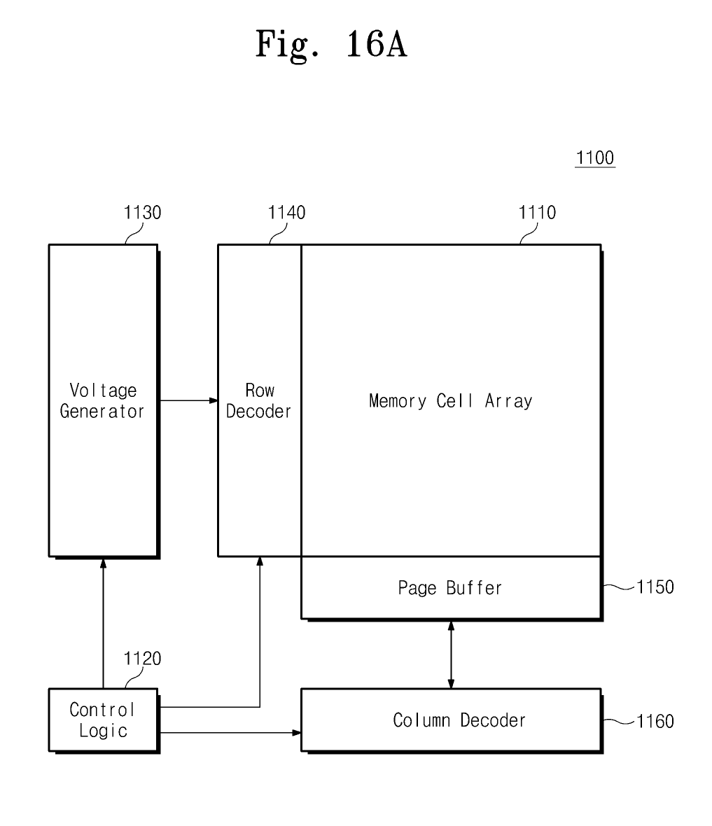

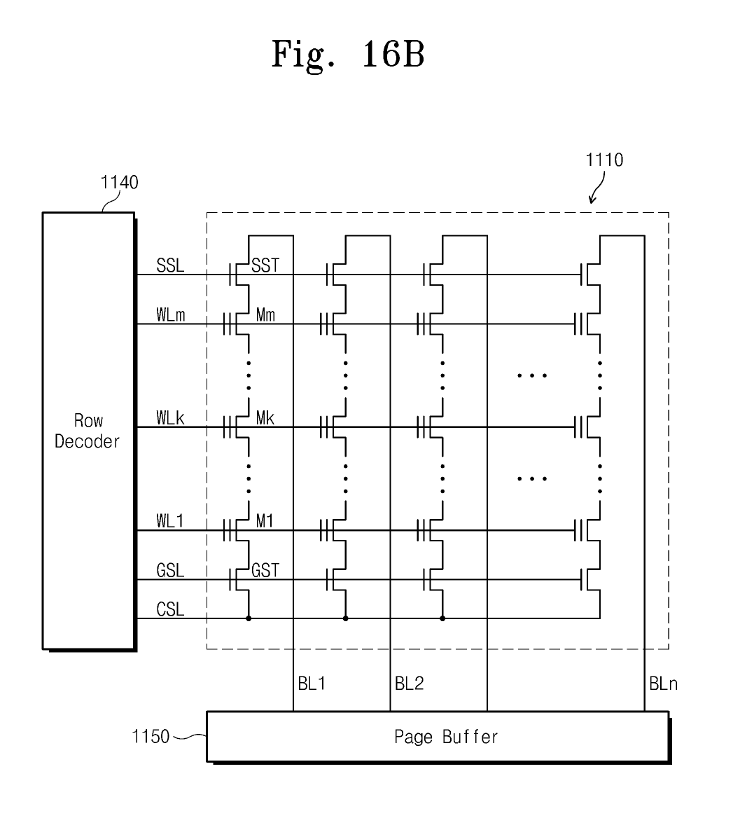

FIG. 15A is a close-up cross-sectional view of a tunnel insulating layer of a previously researched bandgap-engineered (BE) SONOS device having a multiple-layered tunnel insulating layer. FIGS. 15B and 15C are close-up cross-sectional illustrations of a tunnel insulating layer of a memory device having a multiple-layered tunnel insulating layer in accordance with embodiments of the present invention.

Advantages of the configurations of FIGS. 4-8 and the configuration of FIG. 9 will now be described in further detail with reference to FIGS. 15A-15C. As described above, tunnel insulating layers are specifically designed to allow tunneling of holes into the charge storage layer during an erase or programming operation under high electric field conditions, while preventing charge migration during charge retention periods. Devices, in accordance with embodiments of the present invention have been configured to have bandgap-engineered (BE) tunnel insulating layers. The multiple-layered tunnel insulating layer configurations of the embodiments of FIGS. 4-8 and FIG. 9 are the improved examples of BE-SONOS devices. Such devices may include, in these examples, an oxide-nitride-oxide (ONO) tunnel insulating layer 120 positioned between the active region 110, or channel region, of the device and the charge storage layer 130. The tunnel insulating layer 120 has bandgap properties that are specifically designed to provide improved low-field retention characteristics, while offering lowered programming and erase voltage properties. In addition, the tunnel insulating layer 120 including the recessed or protruding middle tunnel layer 124 provides advantageous leakage current characteristics for reasons that will now be described in detail.

With reference to the previously researched embodiment of FIG. 15A, it has been observed that during the formation of conventional tunnel insulating layers having bandgap-engineered tunneling layers, a charge leakage pathway 135a can develop between the charge storage region 130a and the active region 110a along outer edge regions of the multiple tunnel insulating layers 120a. According to our experiment and assumption, the charge leakage pathway 135a develops, for example, due to damage caused at outer edges of the middle tunnel insulating layer 124a during various etching and patterning steps used in the formation of the device. For example, the tunnel insulating layer can become damaged during formation of trenches 180 used to define the isolation structures 160. It is easier for electrons to migrate, or leak, from the charge storage layer 130a to the active region 110a along the outer edges of the middle tunnel layer 124a as a result of the etch damage, than it is for the electrons to migrate from the charge storage layer 130a to the active region 110a through central regions of the middle tunnel layer 124a. For example, in the configuration of FIG. 15A where an ONO multiple-layered tunnel insulating layer 120a is employed, a charge leakage pathway 135a is formed along the outer side edge of the nitride “N” middle layer 124a of the ONO configuration where the nitride layer 124a may be damaged during the various etching steps. Thus, the resulting charge leakage pathway 135a along the outer edge of the nitride middle layer is directly between the charge storage layer 130a and the active region 110a and is in line with the orientation of the electric field between the charge storage layer and the active region in the conventional configuration. As a result, the charge leakage through 135a will be serious, and the retention would not be satisfactory.

In contrast, in a configuration of the type described in connection with the embodiments of the present invention shown in connection with FIGS. 4-8, as shown in the close-up cross-sectional view of FIG. 15B, the middle tunnel layer 124 of the multiple layered tunnel layer 120 protrudes relative to the active region 110. As a result, the charge leakage pathway 136 along an outer edge of the middle tunnel layer 124 is lengthened, for example lengthened by twice the length of the protrusion along upper and lower portions 137a and 137b. As a result, such leakage along the charge leakage pathway 136 is less likely to occur and be suppressed.

In addition, due to the protrusion, a portion of the leakage pathway 136 is perpendicular to the orientation of the electric field between the charge storage layer 130 and the active region 110. As a result, the resulting tunnel insulating layer 120 can offer even further improved isolation properties.

Further, in a configuration of the type described in connection with the embodiments of the present invention shown in connection with FIG. 9, as shown in the close-up view of FIG. 15C, the middle tunnel layer 124 of the multiple layered tunnel layer 120 is recessed relative to the active region 110. As a result, the charge leakage pathway 138 along an outer edge of the middle tunnel layer 124 is lengthened, for example lengthened by twice the length of the recess along upper and lower portions 139a and 139b. As a result, such leakage along the charge leakage pathway 138 is less likely to occur.

In addition, due to the recess, a portion of the leakage pathway 138 is perpendicular to the orientation of the electric field between the charge storage layer 130 and the active region 110. As a result, the resulting tunnel insulating layer 120 can offer even further improved isolation properties. Further, the charge flux in the recess where the middle tunneling layer does not exist is weaker than that in the middle region where upper, lower and middle layer exist. This is assumed that the shape of FN tunneling bandgap of the middle region is much thinner than that in the recess.

Both the protrusion configurations and the recession configurations induce electron tunneling behavior through central regions of the tunneling layer, rather than through the outer edge regions. As a result, retention is improved, and tunneling characteristics are more predictable and more definable, since the characteristics are determined by the properties and thicknesses of the multiple tunneling layers, rather than by a variably damaged outer edge of the multiple tunneling layers.

In some example embodiments, the middle tunnel insulating layer 124a comprises a material that has a bandgap value that is lower than a bandgap value of the material of the lower tunnel insulating layer 122a or a bandgap value of the material of the upper tunnel insulating layer 126a. In other example embodiments, the middle tunnel insulating layer 124a comprises a material that has a dielectric constant value that is higher than a dielectric constant value of the material of the lower tunnel insulating layer 122a or a dielectric constant value of the material of the upper tunnel insulating layer 126a.

In some example embodiments, the material of the middle tunnel insulating layer 124a and the material of the charge storage layer 130 are the same, for example, a silicon nitride based material or other material suitable for charge storage. In other example embodiments, the material of at least one of the lower tunnel insulating layer 122a and the upper tunnel insulating layer 126a is the same as the material of the neighboring isolation structures 160, for example, a silicon oxide based material.

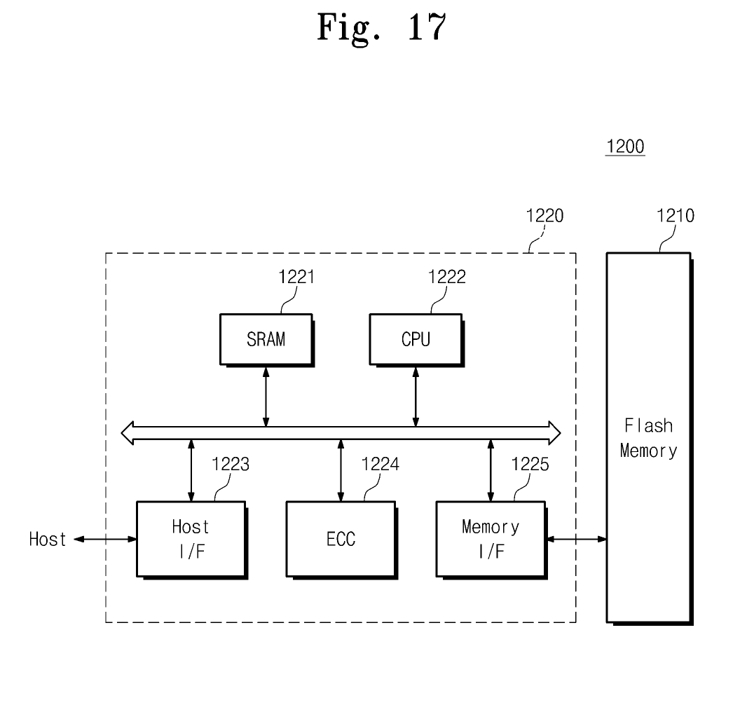

FIG. 16A is a block diagram of a memory device in accordance with embodiments of the present invention. A memory device 1100 includes a memory cell array 1110, control logic 1120, a voltage generator 1130, a row decoder 1140, a page buffer 1150, and a column decoder 1160. The memory cell array 1110 includes a plurality of memory cell strings 20A, 20B of the type described herein, optionally arranged in memory blocks. Control logic 1120 transmits control signals to the voltage generator 1130, the row decoder 1140 and the column decoder 1160 in accordance with the operation to be performed, for example, erase, programming, and read operations. The voltage generator 1130 generates the voltages such as Vpass, Vread, Verase, Vstep voltages required for performing the device operations. The row decoder 1140 determines the manner in which the voltage signals provided by the voltage generator are applied to the lines, such as string select lines SSL, word lines WLk, ground select lines GSL, and common source lines of the memory cell array 1110. The column decoder determines which signals of the bit lines BLn of the device read by the page buffer 1150 are to be used in determining data values that are read, or determines voltages that are applied to the bit lines BLn during programming and erase operations.

FIG. 16B is a block diagram of the memory cell array 1110, of the memory device 1100 of FIG. 16A, in accordance with embodiments of the present invention. In this figure it can be seen that the row decoder 1140 applies the various voltage levels to the one of or more string select lines SSL, the word lines WLk, the ground select line GSL, and the common source line CSL. The page buffer 1150 is connected to the bit lines BLn of the device 1110.

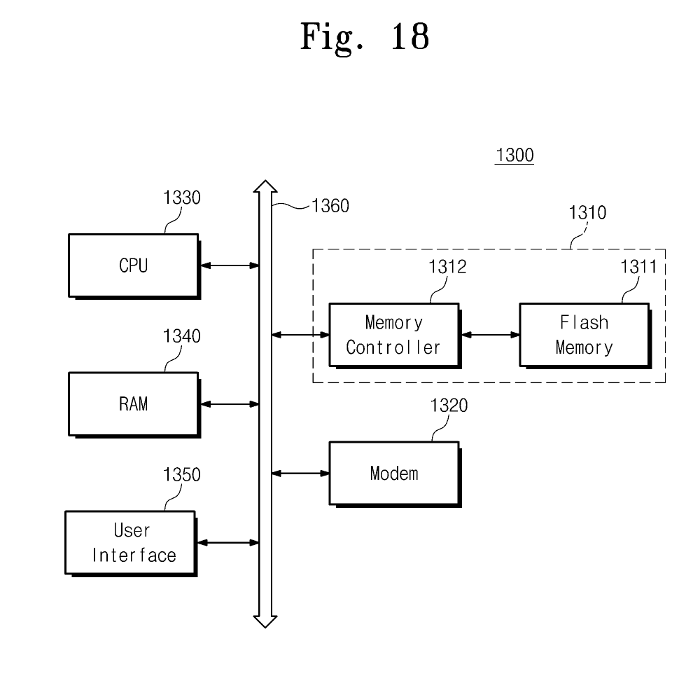

FIG. 17 is a block diagram of a memory card that includes a semiconductor device in accordance with the embodiments of the present invention. The memory card 1200 includes a memory controller 1220 that generates command and address signals C/A and a memory module 1210 for example, flash memory 1210 that includes one or a plurality of flash memory devices. The memory controller 1220 includes a host interface 1223 that transmits and receives command and address signals to and from a host, a controller 1224, and a memory interface 1225 that in turn transmits and receives the command and address signals to and from the memory module 1210. The host interface 1223, the controller 1224 and memory interface 1225 communicate with controller memory 1221 and processor 1222 via a common bus.

The memory module 1210 receives the command and address signals C/A from the memory controller 1220, and, in response, stores and retrieves data DATA I/O to and from at least one of the memory devices on the memory module 1210. Each memory device includes a plurality of addressable memory cells and a decoder that receives the receives the command and address signals, and that generates a row signal and a column signal for accessing at least one of the addressable memory cells during programming and read operations.

Each of the components of the memory card 1200, including the memory controller 1220, electronics 1221, 1222, 1223, 1224, and 1225 included on the memory controller 1220 and the memory module 1210 can employ memory devices that are programmable according to the inventive concepts disclosed herein.

FIG. 18 is a block diagram of a memory system 1300 that employs a memory module 1310, for example, of the type described herein. The memory system 1300 includes a processor 1330, random access memory 1340, user interface 1350 and modem 1320 that communicate via a common bus 1360. The devices on the bus 1360 transmit signals to and receive signals from the memory card 1310 via the bus 1360. Each of the components of the memory system 1300, including the processor 1330, random access memory 1340, user interface 1350 and modem 1320 along with the memory card 1310 can employ vertically oriented memory devices of the type disclosed herein. The memory system 1300 can find application in any of a number of electronic applications, for example, those found in consumer electronic devices such as solid state disks (SSD), camera image sensors (CIS) and computer application chip sets.

The memory systems and devices disclosed herein can be packaged in any of a number of device package types, including, but not limited to, ball grid arrays (BGA), chip scale packages (CSP), plastic leaded chip carrier (PLCC) plastic dual in-line package (PDIP), multi-chip package (MCP), wafer-level fabricated package (WFP), and wafer-level processed stock package (WSP).

While embodiments of the invention have been particularly shown and described with references to preferred embodiments thereof, it will be understood by those skilled in the art that various changes in form and details may be made herein without departing from the spirit and scope of the invention as defined by the appended claims.

1. A memory cell transistor comprising:
an active region, the active region being elongated in a first direction of extension;
a tunnel layer on the active region, the tunnel layer comprising a first tunnel insulating layer, a second tunnel insulating layer on the first tunnel insulating layer and a third tunnel insulating layer on the second tunnel insulating layer;
a charge storage layer on the tunnel layer;
a blocking insulating layer on the charge storage layer; and
a control gate electrode on the blocking insulating layer, the control gate electrode being elongated in a second direction of extension that is transverse the first direction of extension, the active region having a first width in the second direction of extension, the second tunnel insulating layer having a second width in the second direction of extension, the second width being different than the first width.

2. The memory cell transistor of claim 1 wherein the second tunnel insulating layer comprises a material that has a bandgap value that is lower than a bandgap value of a material of the first tunnel insulating layer and a material of the third tunnel insulating layer.

3. The memory cell transistor of claim 1 wherein the second tunnel insulating layer comprises a material that has a dielectric constant value that is higher than a dielectric constant value of a material of the first tunnel insulating layer and a material of the third tunnel insulating layer.

4. The memory cell transistor of claim 1 wherein the second width of the second tunnel insulating layer is greater than the first width of the active region so as to sufficiently increase a length of an edge leakage pathway between the charge storage layer and the active layer along side boundaries of the tunnel layer to thereby minimize electron or hole tunneling at edge regions of the tunnel layer, during programming and erase operations of the memory cell transistor.

5. The memory cell transistor of claim 1 wherein the second width of the second tunnel insulating layer is sufficiently less than the first width of the active region, to thereby minimize electron or hole tunneling at edge regions on the active region, during programming and erase operations of the memory cell transistor.

6. The memory cell transistor of claim 1 wherein the first width of the active region is greater than the second width of the second tunnel insulating layer of the tunnel layer.

7. The memory cell transistor of claim 1 wherein the first width of the active region is less than the second width of the second tunnel insulating layer of the tunnel layer.

8. (canceled)

9. (canceled)

10. (canceled)

11. The memory cell transistor of claim 1 wherein the charge storage layer is of a third width in the second direction of extension and wherein the third width of the charge storage layer is equal to the second width of the second tunnel insulating layer of the tunnel layer.

12. The memory cell transistor of claim 1 wherein the charge storage layer is of a third width in the second direction of extension and wherein the third width of the charge storage layer is greater than the second width of the second tunnel insulating layer of the tunnel layer.

13. The memory cell transistor of claim 1 wherein the charge storage layer is of a third width in the second direction of extension and wherein the third width of the charge storage layer is less than the second width of the second tunnel insulating layer of the tunnel layer.

14. (canceled)

15. The memory cell transistor of claim 1 wherein the second tunnel insulating layer and the charge storage layer are the same material.

16. The memory cell transistor of claim 1 wherein the first tunnel insulating layer comprises silicon oxide, wherein the second tunnel insulating layer comprises silicon nitride and wherein the third tunnel insulating layer comprises silicon oxide.

17. The memory cell transistor of claim 1 wherein the blocking insulating layer includes an opening and wherein the control gate electrode contacts the charge storage layer through the opening in the blocking insulating layer.

18. A semiconductor memory device comprising:
a plurality of active regions defined in a substrate, the active regions each being elongated in a first direction of extension;
a plurality of isolating regions between the active regions, the isolating regions extending in the first direction; the isolating regions insulating the active regions from each other in a second direction of extension that is transverse the first direction;
a tunnel layer on each of the plurality of active regions, the tunnel layer comprising a first tunnel insulating layer, a second tunnel insulating layer on the first tunnel insulating layer and a third tunnel insulating layer on the second tunnel insulating layer;
a charge storage layer on the tunnel layer;
a blocking insulating layer on the charge storage layer; and
a control gate electrode on the blocking insulating layer, the control gate electrode being elongated in the second direction of extension, the active region having a first width in the second direction of extension, the second tunnel insulating layer having a second width in the second direction of extension, the second width being different than the first width;
wherein each of the plurality of active regions extending in the first direction define a transistor string that includes a plurality of memory cell transistors arranged in series between a string select transistor and a ground select transistor, and wherein the semiconductor memory device further comprises:
word lines extending in the second direction and connected to the control gate electrodes of corresponding memory cell transistors of different transistor strings; and
bit lines extending in the first direction and connected to the string select transistors of different transistor strings.

19. The semiconductor memory device of claim 18 wherein each second tunnel insulating layer comprises a material that has a bandgap value that is lower than a bandgap value of a material of the first tunnel insulating layer and a material of the third tunnel insulating layer.

20. The semiconductor memory device of claim 18 wherein each second tunnel insulating layer comprises a material that has a dielectric constant value that is higher than a dielectric constant value of a material of the first tunnel insulating layer and a material of the third tunnel insulating layer.

21. The semiconductor memory device of claim 18 wherein the second width of each second tunnel insulating layer is greater than the first width of the active region.

22. The semiconductor memory device of claim 18 wherein the second width of the second tunnel insulating layer is sufficiently less than the first width of the active region.

23. The semiconductor memory device of claim 18 wherein the first width of the active region is greater than the second width of the second tunnel insulating layer of the tunnel layer.

24. The semiconductor memory device of claim 18 wherein the first width of each active region is less than the second width of the second tunnel insulating layer of the tunnel layer.

25. (canceled)

26. (canceled)

27. (canceled)

28. The semiconductor memory device of claim 18 wherein each charge storage layer is of a third width in the second direction of extension and wherein the third width of the charge storage layer is equal to the second width of the second tunnel insulating layer of the tunnel layer.

29. The semiconductor memory device of claim 18 wherein each charge storage layer is of a third width in the second direction of extension and wherein the third width of the charge storage layer is greater than the second width of the second tunnel insulating layer of the tunnel layer.

30. The semiconductor memory device of claim 18 wherein each charge storage layer is of a third width in the second direction of extension and wherein the third width of the charge storage layer is less than the second width of the second tunnel insulating layer of the tunnel layer.

31. The semiconductor memory device of claim 18 wherein each corresponding second tunnel insulating layer and charge storage layer are the same material

32. The semiconductor memory device of claim 18 wherein the first tunnel insulating layer comprises silicon oxide, wherein the second tunnel insulating layer comprises silicon nitride and wherein the third tunnel insulating layer comprises silicon oxide.

33. The semiconductor memory device of claim 18 wherein the blocking insulating layer includes an opening and wherein the control gate electrode contacts the charge storage layer through the opening in the blocking insulating layer.

34. (canceled)
